(19) United States
(12) Patent Application Publication
(10) Pub. No.: US 2006/0088963 A1
(43) Pub. Date: Apr. 27, 2006

(54) Method of manufacturing semiconductor device

(75) Inventor: Takashi Ipposhi, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Tokyo (JP)

(21) Appl. No.: 11/240,508

(22) Filed: Oct. 3, 2005

(30) Foreign Application Priority Data
Oct. 21, 2004 (JP) 2004-306367

(51) Int. Cl. H01L 21/8234; H01L 21/336

(52) U.S. Cl. 438/197

(57) ABSTRACT

An oxide film is formed on an SOI layer, an isolation oxide film and a gate electrode. A nitride film is formed on the oxide film. Next, anisotropic etching is performed only on the nitride film to form sidewalls on opposite side surfaces of the gate electrode. Thus, the oxide film is not etched. Next, an N-type impurity is implanted through the oxide film to form source/drain regions in an upper portion of the SOI layer. In this step, adjusting the implantation energy so that the impurity reaches the buried oxide film provides the source/drain regions in contact with the buried oxide film.

### BACKGROUND OF THE INVENTION

1. Field of the Invention

The present invention relates to a method of manufacturing a semiconductor device and, more particularly, to a method of manufacturing a semiconductor device including a MOSFET formed on a thin-film SOI (Silicon On Insulator).

2. Description of the Background Art

A procedure for the formation of a MOSFET having a partial trench isolation structure on a thin film SOI in a conventional semiconductor device will be described.

First, a buried oxide film, an SOI layer, and an underlying oxide film are formed in the order named on a Si substrate. Next, an isolation oxide film is formed to extend through the underlying oxide film to some mid-portion in the SOI layer. Next, impurities are implanted as a channel dopant. Thereafter, the underlying oxide film is removed. Next, a gate oxide film and a gate polysilicon layer are formed on the SOI layer and the isolation oxide film, and are then patterned, whereby sidewalls are formed on opposite side surfaces of a gate electrode. Next, impurities are implanted onto the SOI layer to form an extension. Thereafter, an oxide film and a nitride film are formed. Next, anisotropic etching is performed on the oxide film and the nitride film to form sidewalls. Next, impurities are implanted to form a source/drain region in an upper portion of the SOI layer. The above-mentioned steps are executed to produce the MOSFET having the partial trench isolation structure.

Conventional methods of manufacturing MOSFETs or conventional partial trench isolation structures are disclosed in: Japanese Patent Application Laid-Open No. 5-218072 (1993); Japanese Patent Application Laid-Open No. 2004-31492; DIGEST OF TECHNICAL PAPERS, pp. 131-132, “Bulk-Layout-Compatible 0.18 μm SOI-CMOS Technology Using Body-Fixed Partial Trench Isolation (PTI)”, Y. Hirano, S. Maeda, T. Matsumoto, K. Nii, T. Iwamatsu, Y. Yamaguchi, T. Ipposhi, H. Kawashima, S. Maegawa, M. Inuishi and T. Nishimura, 1999 IEEE International SOI Conference, October 1999; DIGEST OF TECHNICAL PAPERS, pp. 154-155, “Impact of 0.18 μm SOI CMOS Technology using Hybrid Trench Isolation with High Resistivity Substrate on Embedded RF/Analog Applications”, S. Maeda, Y. Wada, K. Yamamoto, H. Komurasaki, T. Matsumoto, Y. Hirano, T. Iwamatsu, Y. Yamaguchi, T. Ipposhi, K. Ueda, K. Mashiko, S. Maegawa, and M. Uniishi, VLSI Technology, 2000 Symposium; and “80 nm CMOSFET Technology Using Double Offset-Implanted Source/Drain Extension and Low Temperature SiN Process”, H. Sayama, Y. Nishida, H. Oda, J. Tsuchimoto, H. Umeda, A. Teramoto, K. Eikyu, Y. Inoue and M. Inuishi, 2000 IEEE IEDM.

For the formation of the source/drain region in the conventional method of manufacturing the semiconductor device, implantation energy is adjusted so that the impurities reach the buried oxide film for the purpose of reduction in parasitic capacitance. However, the execution of the anisotropic etching on the oxide film and the nitride film during the formation of the sidewalls results in overetching to significantly reduce the thickness of the isolation oxide film. For this reason, when the impurities are implanted so as to reach the buried oxide film, the impurities penetrate through the isolation oxide film into the SOI layer lying under the isolation oxide film. Thus, the conventional method presents the problem of the occurrence of an isolation failure.

To prevent such an isolation failure, it is contemplated to decrease the impurity implantation energy. In such a case, however, another problem arises that the impurities for the formation of the source/drain region do not reach the buried oxide film to result in the increase in parasitic capacitance.

### SUMMARY OF THE INVENTION

It is an object of the present invention to provide a method of manufacturing a semiconductor device capable of reducing a parasitic capacitance while preventing an isolation failure.

A first aspect of the present invention is intended for a method of manufacturing a semiconductor device. According to the present invention, the method includes the following steps (a) through (g). The step (a) is to form a buried oxide film and an SOI layer in the order named on a substrate. The step (b) is to form an isolation insulation film having a bottom surface positioned inside the SOI layer for partially isolating the SOI layer. The step (c) is to form a gate electrode on the SOI layer. The step (d) is to form a first oxide film so as to cover the gate electrode. The step (e) is to form a nitride film on the first oxide film. The step (f) is to etch the nitride film, with the first oxide film left unremoved, thereby to form a sidewall. The step (g) is to implant a first impurity into the SOI layer through the first oxide film to form a first source/drain region.

The method avoids the significant reduction in the thickness of the isolation oxide film to achieve the formation of the first source/drain region in contact with the buried oxide film without the occurrence of an isolation failure. Therefore, the method is capable of reducing a parasitic capacitance while preventing the isolation failure. Additionally, the first oxide film is used for the purpose of preventing silicide deposition, thereby to reduce mechanical stress on a transistor during the deposition. Furthermore, the method can make an anti-silicidation film thin to improve throughput.

A second aspect of the present invention is intended for a method of manufacturing a semiconductor device. According to the present invention, the method includes the following steps (a) through (g). The step (a) is to form a buried oxide film and an SOI layer in the order named on a substrate. The step (b) is to form an isolation insulation film having a bottom surface positioned inside the SOI layer for partially isolating the SOI layer. The step (c) is to form a gate electrode on the SOI layer. The step (d) is to form a first oxide film so as to cover the gate electrode. The step (e) is to form a nitride film and a second oxide film in the order named on the first oxide film. The step (f) is to etch the nitride film and the second oxide film, with the first oxide film left unremoved, thereby to form a sidewall. The step (g) is to implant a first impurity into the SOI layer through the first oxide film to form a first source/drain region.

The method achieves the reduction in mechanical stress on the transistor during the deposition and the prevention of the silicide deposition more effectively. Therefore, the method improves the characteristics of the transistor and improves yields.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 through 6 are sectional views showing a method of manufacturing a semiconductor device according to a first preferred embodiment of the present invention;

FIGS. 7 and 8 are sectional views showing a method of manufacturing a semiconductor device according to a second preferred embodiment of the present invention;

FIGS. 9 and 10 are sectional views showing a method of manufacturing a semiconductor device according to a third preferred embodiment of the present invention;

FIGS. 11 through 13 are sectional views showing a method of manufacturing a semiconductor device according to a fourth preferred embodiment of the present invention;

FIGS. 14 and 15 are sectional views showing a method of manufacturing a semiconductor device according to a fifth preferred embodiment of the present invention; and

FIGS. 16 through 19 are sectional views showing a method of manufacturing a semiconductor device according to a sixth preferred embodiment of the present invention.

### DESCRIPTION OF THE PREFERRED EMBODIMENTS

### First Preferred Embodiment

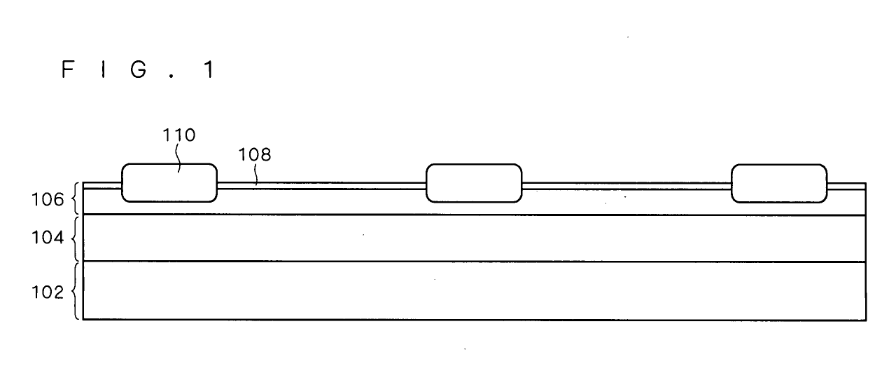

FIGS. 1 through 6 are sectional views showing a method of manufacturing a semiconductor device according to a first preferred embodiment of the present invention. This semiconductor device shall include an NMOSFET having a partial trench isolation structure formed on a thin-film SOI (Semiconductor On Insulator).

First, as illustrated in FIG. 1, a buried oxide film 104 having a thickness of about 150 nm, an SOI layer 106 made of single crystal silicon having a crystallinity and having a thickness of about 130 nm, and an underlying oxide film 108 having a thickness of about 15 nm are formed in the order named on a Si substrate 102. Next, an amorphous isolation oxide film 110 (isolation insulation film) having a thickness of about 150 nm is formed so as to penetrate through the underlying oxide film 108 to a mid-portion of the SOI layer 106. That is, the isolation oxide film 110 is formed so that a bottom surface thereof is positioned inside the SOI layer 106, and partially isolates the SOI layer 106 (a partial trench isolation structure). In this step, a portion of the SOI layer 106 which lies under the isolation oxide film 110 has a thickness of about 40 nm. Next, boron (B) which is a P-type impurity is implanted as a channel dopant from over the SOI layer 106. Although depending on a threshold value to be set, it is desirable that the impurity concentration is about 1E17 to 1 E18/cm³. For the formation of a PMOSFET, rather than the NMOSFET, in a CMOS structure, an N-type impurity such as arsenic (As) and phosphorus (P) is implanted as the channel dopant in place of boron. In such a case, the region of implantation is defined by using a resist mask as appropriate.

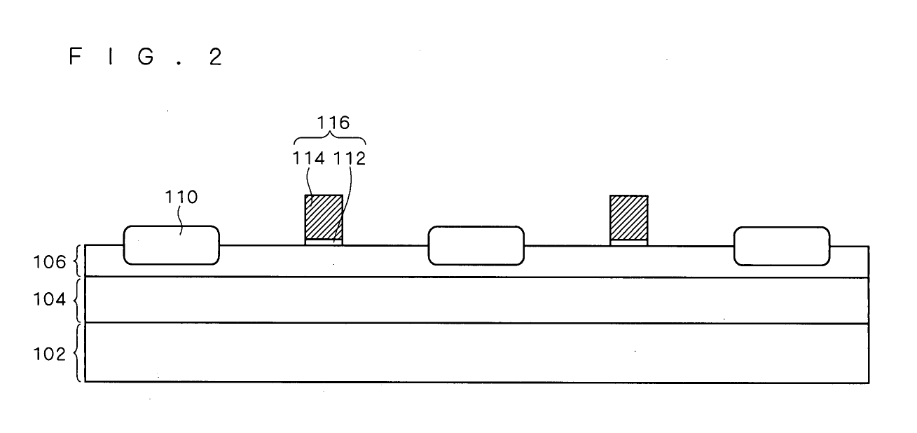

Next, as illustrated in FIG. 2, the underlying oxide film 108 is removed. Next, a gate oxide film 112 and a gate polysilicon layer 114 are formed in the order named on the SOI layer 106 and the isolation oxide film 110. A gate electrode 116 is formed by patterning the gate oxide film 112 and the gate polysilicon layer 114.

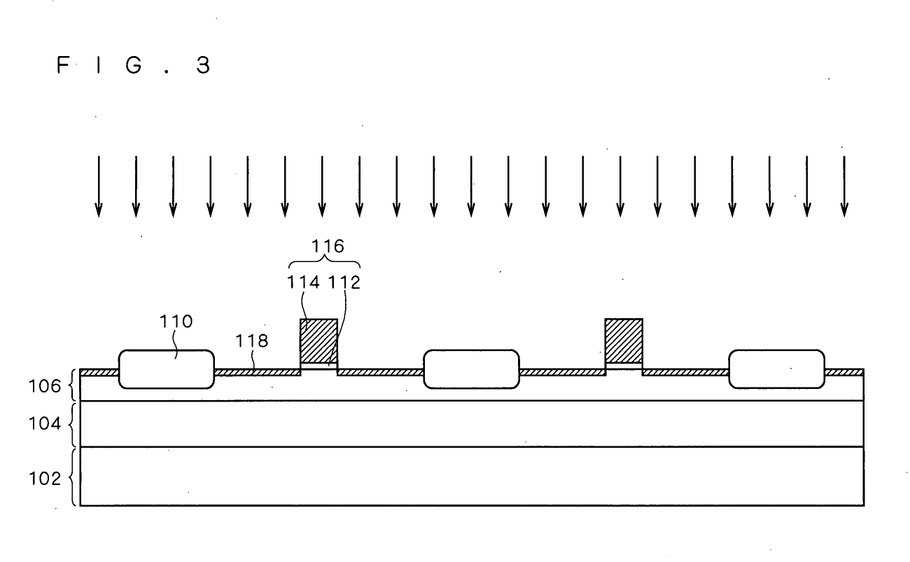

Next, as illustrated in FIG. 3, arsenic which is an N-type impurity is implanted to form extensions 118. In general, it is desirable that the impurity concentration in this step is about 1E19 to 1E21/cm³.

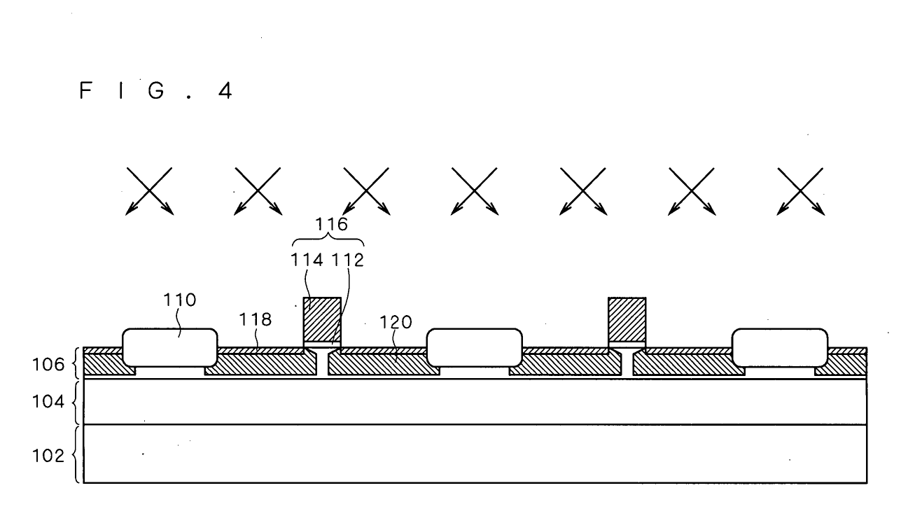

Next, as illustrated in FIG. 4, pocket implantation of boron which is a P-type impurity is performed to form pocket implantation layers 120. In general, it is desirable that the impurity concentration in this step is equal to or higher than the concentration of the channel dopant, and is about 5E17 to 5E18/cm³.

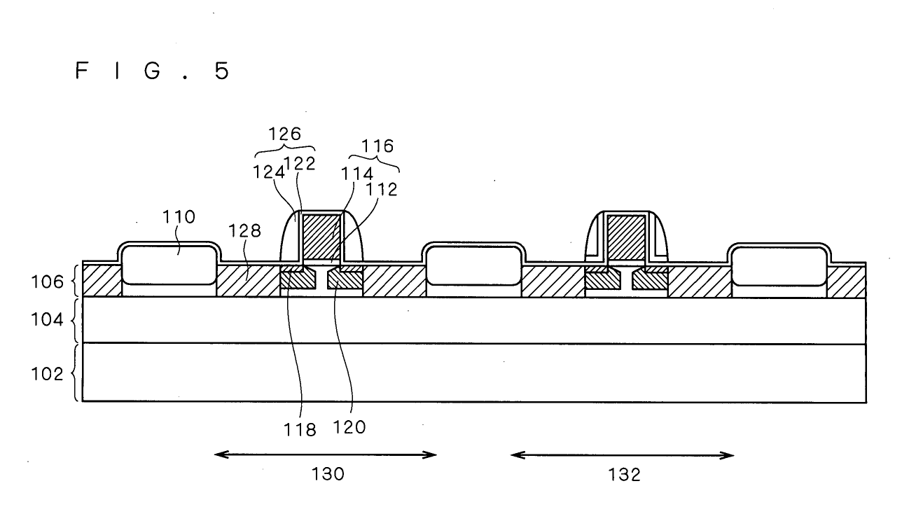

Next, as illustrated in FIG. 5, an oxide film 122 (a first oxide film) having a thickness of about 10 nm is formed on the SOI layer 106, the isolation oxide film 110 and the gate electrode 116 so as to cover the gate electrode 116. Next, a nitride film 124 is formed on the oxide film 122. Next, anisotropic etching is performed only on the nitride film 124 to form sidewalls 126 on opposite side surfaces of the gate electrode 116. Thus, the oxide film 122 is hardly etched. The use of two types of films different in etch rate from each other enables the nitride film 124 to be etched while the oxide film 122 is hardly etched. This allows the reduction in variations in transistor characteristics due to large variations in remaining film thickness of the oxide film 122.

Next, an N-type impurity (a first impurity) including arsenic or phosphorus is implanted through the oxide film 122 to form source/drain regions 128 (a first source/drain region) in the SOI layer 106. In this step, adjusting the implantation energy so that the impurity reaches the buried oxide film 104 provides the source/drain regions 128 in contact with the buried oxide film 104. This achieves the reduction in parasitic capacitance in the source/drain regions 128. The above-mentioned process steps produce transistor regions 130 and 132 including MOSFETs in the semiconductor device having the partial trench isolation structure.

As mentioned above, the conventional method of manufacturing the semiconductor device etches the oxide film 122 in addition to the nitride film 124 during the formation of the sidewalls 126 to result in overetching, thereby significantly reducing the thickness of the isolation oxide film 110. The first preferred embodiment etches only the nitride film 124 to avoid the significant reduction in the thickness of the isolation oxide film 110. Therefore, the first preferred embodiment prevents the impurity from penetrating through the isolation oxide film 110 when the impurity is implanted so as to reach the buried oxide film 104 for the formation of the source/drain regions 128.

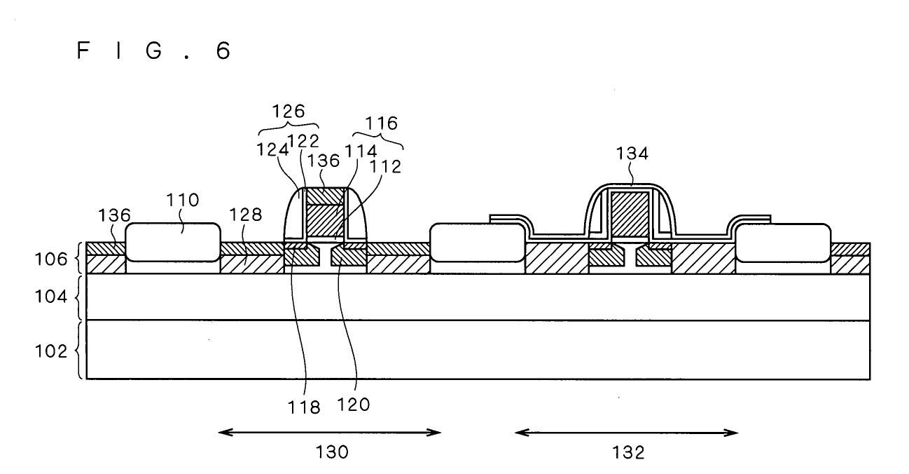

Next, as illustrated in FIG. 6, the N-type impurity implanted for the formation of the source/drain regions 128 is activated by lamp annealing and the like, and an anti-silicidation film 134 made of an oxide is formed entirely on the top surface. Then, the anti-silicidation film 134 is patterned so as to remain in the transistor region 132 for I/O purpose and the like in which a silicide layer 136 is not to be formed and so as not to remain in the transistor region 130 in which the silicide layer 136 is to be formed. In this step, the oxide film 122 is patterned at the same time. Next, the silicide layer 136 made of CoSi₂, NiSi or the like is selectively formed in an upper portion of the SOI layer 106 and in an upper portion of the gate polysilicon layer 114. Next, an integrated circuit is prepared by the use of a known contact formation technique and a known multi-level interconnection formation technique (which will not be described in detail herein). This manufactures the semiconductor device including the MOSFETs having the partial trench isolation structure formed on the thin-film SOI. Although a flow of manufacturing steps in which the anti-silicidation film 134 is provided is described above as an example, a flow of manufacturing steps for a product employing no anti-silicidation film 134 includes the step of removing the oxide film 122 to expose a silicon surface prior to the formation of the silicide layer.

As described hereinabove, the method of manufacturing the semiconductor device according to the first preferred embodiment includes the step of performing anisotropic etching only on the nitride film 124 for the formation of the sidewalls 126. This avoids the significant reduction in the thickness of the isolation oxide film 110 to achieve the formation of the source/drain regions 128 in contact with the buried oxide film 104 without the occurrence of an isolation failure. Therefore, the first preferred embodiment is capable of reducing a parasitic capacitance while preventing the isolation failure.

Additionally, the oxide film 122 is used for the purpose of preventing the deposition of the silicide by patterning the oxide film 122 at the same time as the anti-silicidation film 134. Thus, mechanical stress on the transistors are reduced during the deposition. Furthermore, the first preferred embodiment can make the anti-silicidation film 134 thin to improve throughput.

### Second Preferred Embodiment

In the first preferred embodiment, the source/drain regions 128 are formed in the upper portion of the SOI layer 106 by implanting the N-type impurity including arsenic or phosphorus through the oxide film 122 with reference to FIG. 5 after the execution of the pocket implantation with reference to FIG. 4. However, the N-type impurity may be implanted prior to the formation of the source/drain regions 128.

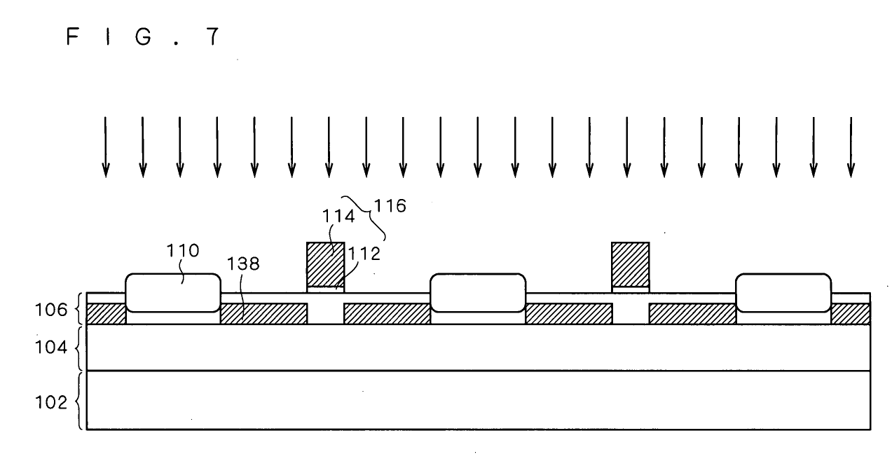

FIG. 7 is a sectional view showing a method of manufacturing a semiconductor device according to a second preferred embodiment of the present invention. As illustrated in FIG. 7, phosphorus which is an N-type impurity (a second impurity) similar in concentration to the channel dopant is implanted after the formation of the gate electrode 116 according to the second preferred embodiment.

As discussed in the first preferred embodiment with reference to FIG. 1, the SOI layer 106 is a P-type semiconductor because boron which is the P-type impurity is implanted as the channel dopant into the SOI layer 106. Thus, the implantation of phosphorus which is the N-type impurity provides the SOI layer 106 as a P-type semiconductor having a low effective impurity concentration (or an N-type semiconductor having a low effective impurity concentration), as shown in FIG. 7. This lowers the effective concentration of the P-type impurity near regions in which the source/drain regions 128 are to be formed in a subsequent step. This implantation is referred to hereinafter as “counter source/drain implantation,” and regions of a low effective P-type impurity concentration formed by the counter source/drain implantation are referred to hereinafter as counter source/drain regions 138 (a second source/drain region).

For the above-mentioned counter source/drain implantation, adjusting the implantation energy so that the phosphorus reaches the buried oxide film 104 allows a low P-type impurity concentration near an interface between the buried oxide film 104 and the SOI layer 106.

In this step, implanting the phosphorus in a direction perpendicular to the upper surface of the SOI layer 106 enables the phosphorus to be introduced deeply through to the buried oxide film 104 with lower implantation energy because of a channeling effect. This channeling effect occurs in the SOI layer 106 having a crystallinity, but does not occur in the amorphous isolation oxide film 110. Therefore, the deep implantation of the impurity is accomplished without the penetration of the impurity through the isolation oxide film 110.

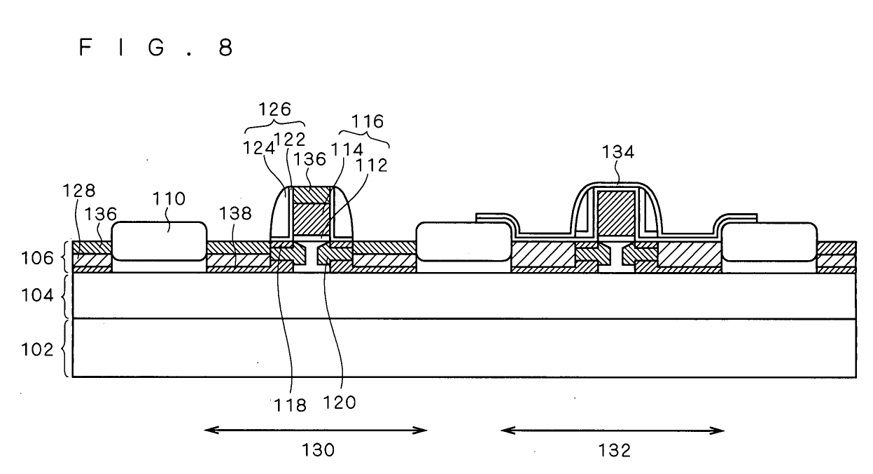

Next, as illustrated in FIG. 8, arsenic which is the N-type impurity is implanted to form the extensions 118.

Subsequently, a procedure similar to that of the first preferred embodiment is carried out to manufacture the semiconductor device as shown in the sectional view of FIG. 8. FIG. 8 shows that the counter source/drain regions 138 are formed near regions in which the source/drain regions 128 shown in FIG. 6 are to be formed.

As described hereinabove, the method of manufacturing the semiconductor device according to the second preferred embodiment includes the step of performing the counter source/drain implantation after the formation of the gate electrode 116 to decrease the effective P-type impurity concentration near the regions in which the source/drain regions 128 are to be formed in a subsequent step. Thus, if the implantation energy of the N-type impurity for the formation of the source/drain regions 128 is decreased, the source/drain regions 128 are in electrical contact with the buried oxide film 104 through the counter source/drain regions 138, whereby the parasitic capacitance is reduced. This allows the decrease in the implantation energy of the N-type impurity for the formation of the source/drain regions 128, thereby to enhance the effect of preventing the isolation failure, as compared with the first preferred embodiment.

### Third Preferred Embodiment

In the second preferred embodiment, the counter source/drain implantation is performed after the gate electrode 116 is formed with reference to FIG. 2 of the first preferred embodiment. However, the counter source/drain implantation need not be performed only after the formation of the gate electrode 116, but may be performed after the oxide film 122 is formed with reference to FIG. 5 of the first preferred embodiment.

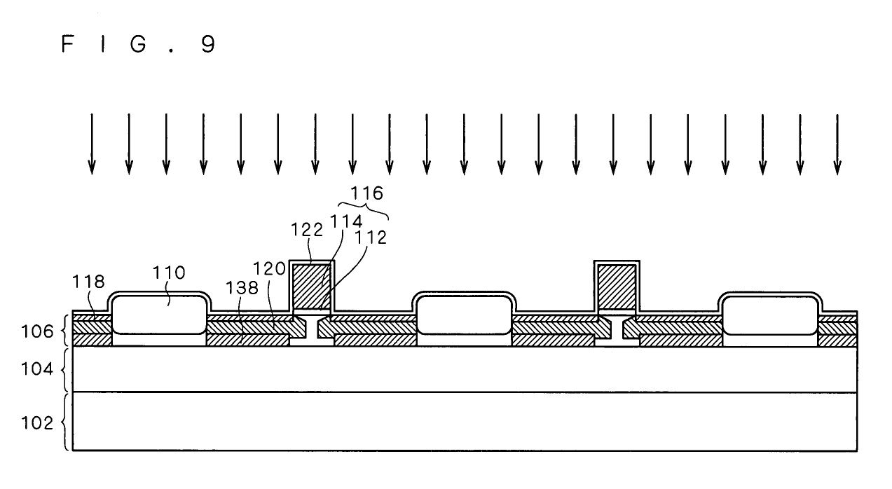

FIG. 9 is a sectional view showing a method of manufacturing a semiconductor device according to a third preferred embodiment of the present invention. As illustrated in FIG. 9, the counter source/drain implantation is performed after the formation of the oxide film 122 according to the third preferred embodiment. The implantation through the oxide film 122 achieves the formation of the counter source/drain regions 138 more outside of the gate electrode 116 (that is, more outside than the extensions 118). Therefore, the short channel effects due to the counter source/drain implantation are reduced.

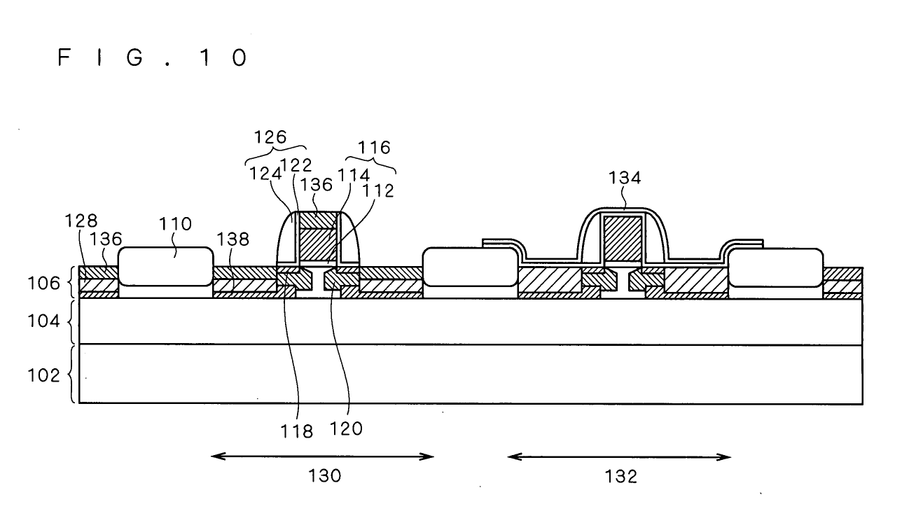

Next, as illustrated in FIG. 10, the nitride film 124 is formed on the oxide film 122. Next, anisotropic etching is performed only on the nitride film 124 to form the sidewalls 126 on the opposite side surfaces of the gate electrode 116.

Subsequently, a procedure similar to that of the first preferred embodiment is carried out to manufacture the semiconductor device as shown in the sectional view of FIG. 10. FIG. 10 shows that the counter source/drain regions 138 shown in FIG. 8 are formed more outside of the gate electrode 116.

As described hereinabove, the method of manufacturing the semiconductor device according to the third preferred embodiment includes the step of performing the counter source/drain implantation after the formation of the oxide film 122 to form the counter source/drain regions 138 more outside of the gate electrode 116. Therefore, the third preferred embodiment produces the effect of reducing the short channel effects to reduce degradation, in addition to the effect produced by the second preferred embodiment.

### Fourth Preferred Embodiment

In the first preferred embodiment, the sidewalls 126 each having a two-layer structure composed of the oxide film 122 and the nitride film 124 are formed with reference to FIG. 5. However, sidewalls having a three-layer structure may be formed in place of the sidewalls 126.

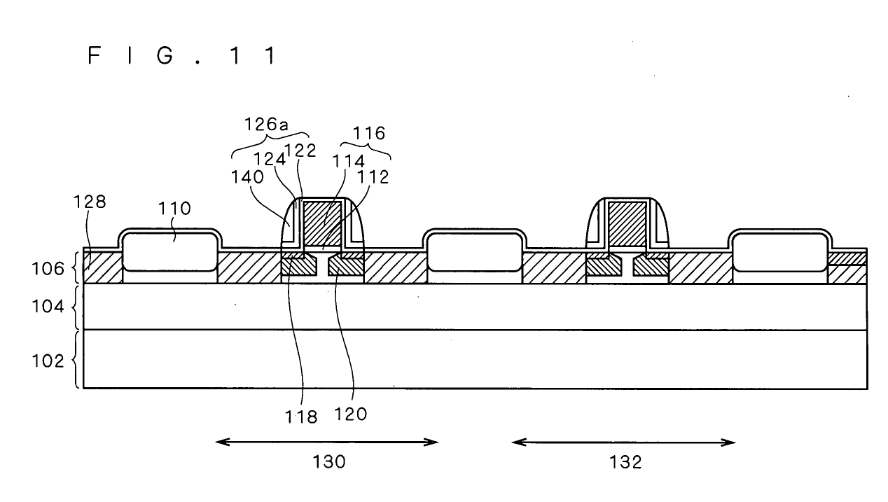

FIG. 11 is a sectional view showing a method of manufacturing a semiconductor device according to a fourth preferred embodiment of the present invention. As illustrated in FIG. 11, the oxide film 122 is formed on the SOI layer 106, the isolation oxide film 110 and the gate electrode 116 after the formation of the pocket implantation layers 120. Next, the nitride film 124 is formed on the oxide film 122. Next, an oxide film 140 (a second oxide film) is formed on the nitride film 124. Next, anisotropic etching is performed on the nitride film 124 and the oxide film 140 to form sidewalls 126a having the three-layer structure. In this step, the oxide film 122 is not etched in a manner similar to the first preferred embodiment. The formation of the sidewalls 126a having the three-layer structure allows the change and further reduction in mechanical stress on the transistors during the deposition. Additionally, the formation of the oxide film 140 in which a silicide is more difficult to grow than in the nitride film 124 allows the suppression of the abnormal growth of the silicide layer 136 on the sidewalls 126a.

Next, an N-type impurity including arsenic or phosphorus is implanted through the oxide film 122 to form the source/drain regions 128 in the upper portion of the SOI layer 106.

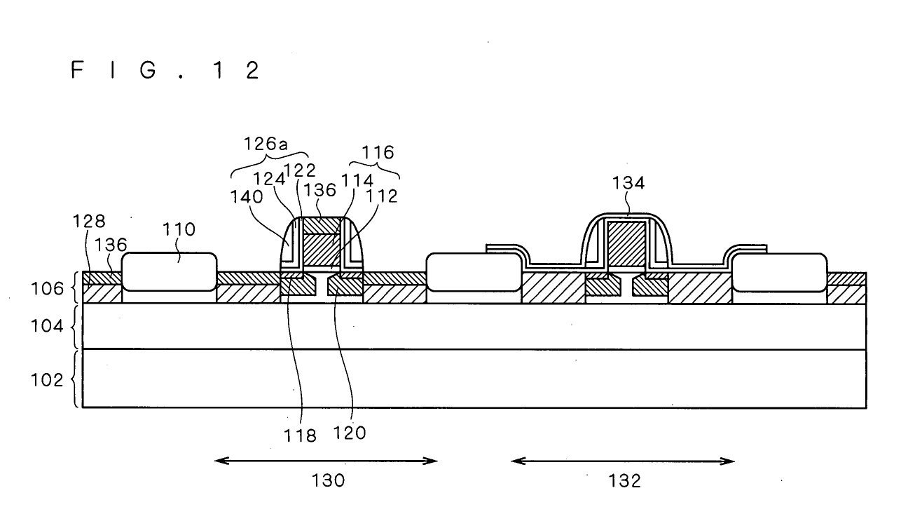

Subsequently, a procedure similar to that of the first preferred embodiment is carried out to manufacture the semiconductor device as shown in the sectional view of FIG. 12. FIG. 12 shows that the sidewalls 126a having the three-layer structure are formed in place of the sidewalls 126 shown in FIG. 6.

As described hereinabove, the method of manufacturing the semiconductor device according to the fourth preferred embodiment includes the step of forming the sidewalls 126a having the three-layer structure to allow the change and further reduction in mechanical stress on the transistors during the deposition, and the suppression of the abnormal growth of the silicide layer 136 on the sidewalls 126a. Therefore, the fourth preferred embodiment produces the effects of improving the characteristics of the transistor regions 130 and 132 and improving yields, in addition to the effect produced by the first preferred embodiment.

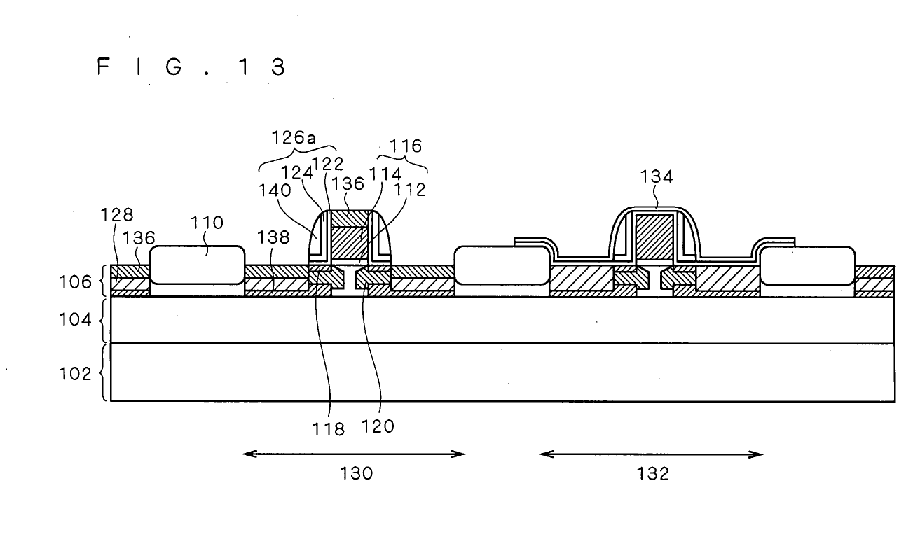

FIG. 13 shows that the sidewalls 126a having the three-layer structure are formed in place of the sidewalls 126 with reference to FIG. 8 of the second preferred embodiment. This produces the effects of improving the characteristics of the transistor regions 130 and 132 and improving yields, in addition to the effect produced by the second preferred embodiment.

### Fifth Preferred Embodiment

In the third preferred embodiment, the sidewalls 126 each having a two-layer structure composed of the oxide film 122 and the nitride film 124 are formed with reference to FIG. 10. However, the sidewalls 126a having the three-layer structure may be formed in place of the sidewalls 126 in a manner similar to the fourth preferred embodiment.

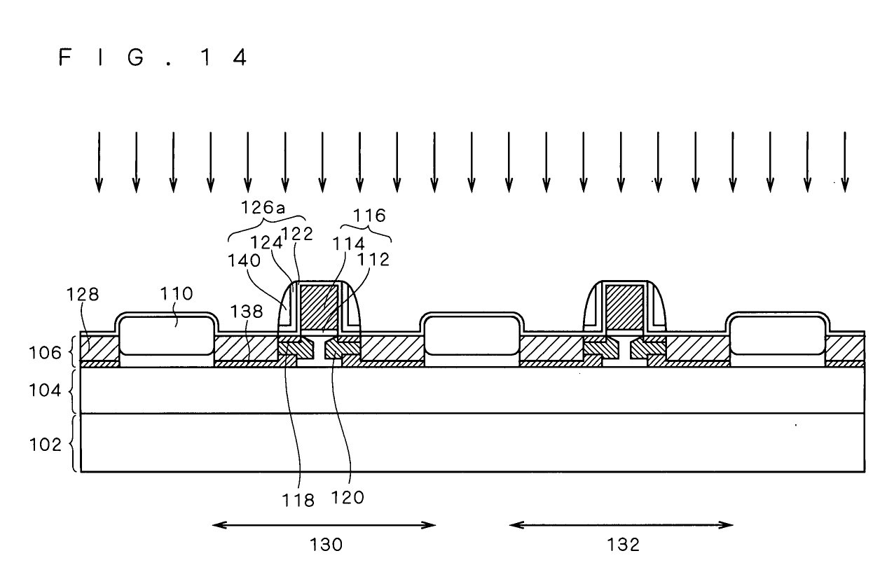

FIG. 14 is a sectional view showing a method of manufacturing a semiconductor device according to a fifth preferred embodiment of the present invention. As illustrated in FIG. 14, the counter source/drain implantation is performed after the formation of the oxide film 122 in a manner similar to the third preferred embodiment. Next, the nitride film 124 is formed on the oxide film 122 in a manner similar to the fourth preferred embodiment. Next, the oxide film 140 is formed on the nitride film 124. Next, anisotropic etching is performed on the nitride film 124 and the oxide film 140 to form the sidewalls 126a having the three-layer structure.

Next, an N-type impurity including arsenic or phosphorus is implanted through the oxide film 122 to form the source/drain regions 128 in the upper portion of the SOI layer 106.

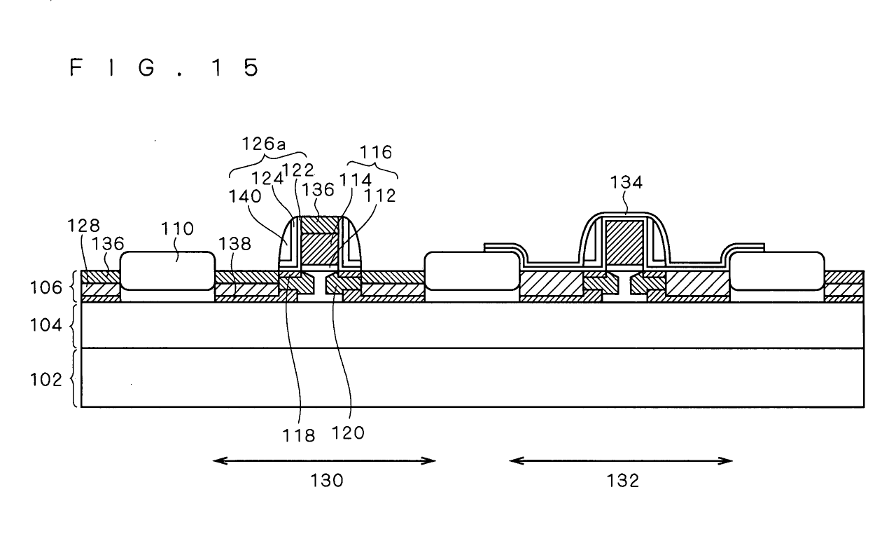

Subsequently, a procedure similar to that of the first preferred embodiment is carried out to manufacture the semiconductor device as shown in the sectional view of FIG. 15. FIG. 15 shows that the sidewalls 126a having the three-layer structure are formed in place of the sidewalls 126 shown in FIG. 10.

As described hereinabove, the method of manufacturing the semiconductor device according to the fifth preferred embodiment includes the step of forming the sidewalls 126a having the three-layer structure in a manner similar to the fourth preferred embodiment in the method of manufacturing the semiconductor device according to the third preferred embodiment. Therefore, the fifth preferred embodiment produces the effects produced by both the third and fourth preferred embodiments.

Although the description has been given hereinabove by taking the NMOSFET as an example, the present invention is capable of reducing the parasitic capacitance while preventing the isolation failure similarly in a PMOSFET, as described above. Thus, the implantation steps (the channel doping, the extension implantation, the pocket implantation, the counter source/drain implantation, and the source/drain implantation) may be performed while forming resist masks as appropriate for a CMOS device including an NMOSFET and a PMOSFET. Boron which is implanted as the P-type impurity to form source/drain regions in the PMOSFET has a greater diffusion length as compared with an N-type impurity, thereby to allow the reduction in implantation energy. Therefore, forming the CMOS device in such a manner that the counter source/drain implantation is not performed during the formation of the PMOSFET but is performed only during the formation of the NMOSFET improves the performance of the CMOS device and simplifies the processes.

### Sixth Preferred Embodiment

The semiconductor device which does not have an offset source/drain structure is described in the first preferred embodiment. The semiconductor device according to the present invention, however, may have the offset source/drain structure.

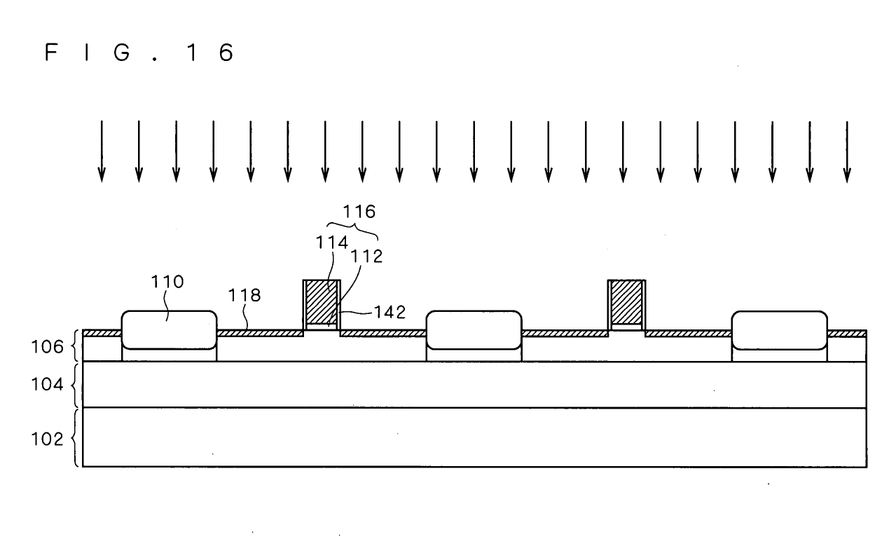

FIG. 16 is a sectional view showing a method of manufacturing a semiconductor device according to a sixth preferred embodiment of the present invention. As illustrated in FIG. 16, offset oxide films 142 (an offset insulation film) are formed on the opposite side surfaces of the gate electrode 116 after the formation of the gate electrode 116 according to the sixth preferred embodiment.

Next, arsenic is implanted to form the extensions 118 in a manner similar to the first preferred embodiment.

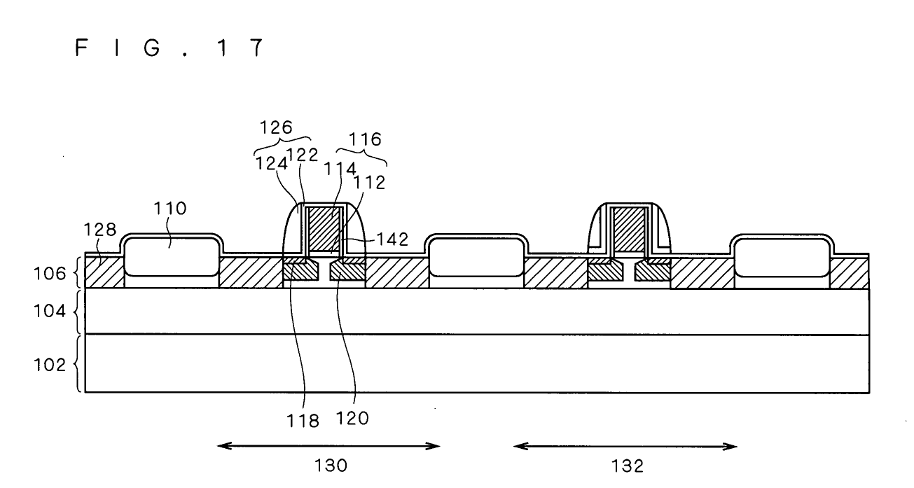

Subsequently, a procedure similar to that of the first preferred embodiment is carried out to form the transistor regions 130 and 132 as shown in the sectional view of FIG. 17, thereby manufacturing the semiconductor device. FIG. 17 shows that the offset oxide films 142 are formed on the opposite side surfaces of the gate electrode 116 with reference to FIG. 5, and the gate electrode 116 and the offset oxide films 142 are integrally covered with the oxide film 122.

As described hereinabove, the method of manufacturing the semiconductor device according to the sixth preferred embodiment includes the step of forming the offset oxide films 142 on the opposite sides of the gate electrode 116 after the formation of the gate electrode 116. Therefore, the sixth preferred embodiment produces the effect of adjusting the thickness of the offset oxide films 142 to adjust the characteristics such as a channel length and the like in addition to the effect produced by the first preferred embodiment.

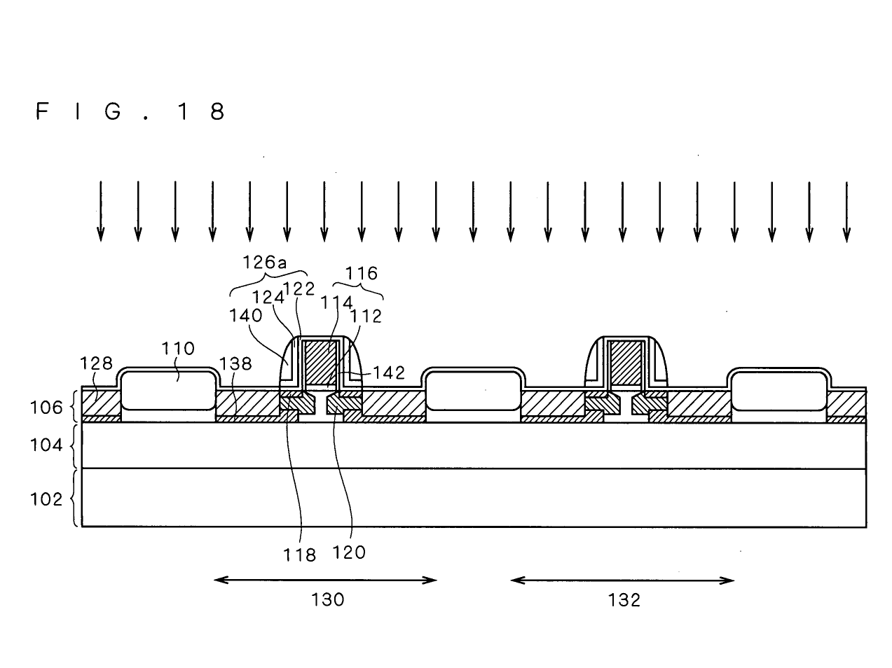

Although the offset source/drain structure is illustrated as applied to the first preferred embodiment, the offset source/drain structure may be applied not only to the first preferred embodiment but also to the second to fifth preferred embodiments. FIG. 18 shows that the offset oxide films 142 are formed on the opposite side surfaces of the gate electrode 116 with reference to FIG. 14 of the fifth preferred embodiment. This produces the effect of adjusting the characteristics such as the channel length and the like in addition to the effect produced by the fifth preferred embodiment.

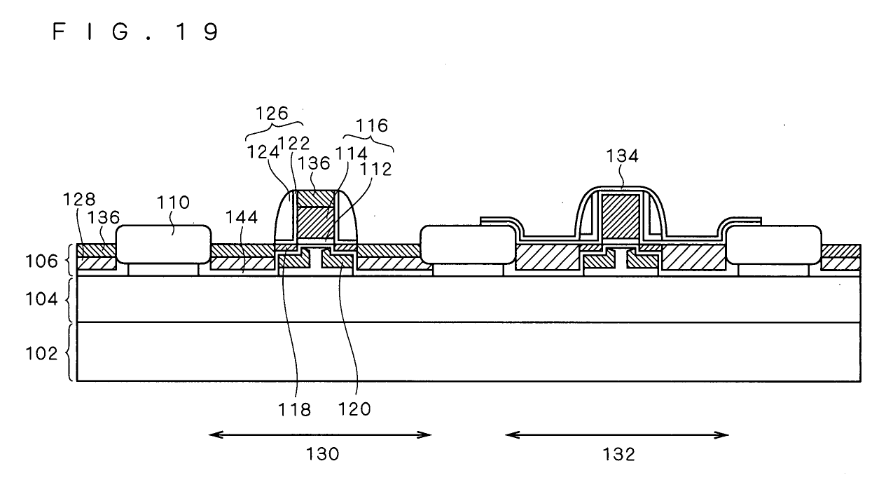

In the above description, the implanted N-type impurity is illustrated as reaching the buried oxide film 104 whereby the source/drain regions 128 are formed in contact with the buried oxide film 104. However, as schematically illustrated in FIG. 19, even if the impurity does not reach the buried oxide film 104 so that the source/drain regions 128 are not in contact with the buried oxide film 104, the parasitic capacitance is reduced when depletion layers 144 extending from the source/drain regions 128 are in contact with the buried oxide film 104, with no voltage applied to the source/drain regions 128. FIG. 19 shows that the depletion layers 144 are formed under the source/drain regions 128 with reference to FIG. 6. As mentioned above, the implantation energy of the impurity is preferably lowered for the purpose of preventing the isolation failure resulting from the penetration of the impurity through the isolation oxide film. Thus, the effect of preventing the isolation failure is further enhanced by performing implantation with such low energy that the depletion layers 144 are in contact with the buried oxide film 104 although the impurity does not reach the buried oxide film 104.

While the invention has been described in detail, the foregoing description is in all aspects illustrative and not restrictive. It is understood that numerous other modifications and variations can be devised without departing from the scope of the invention.

What is claimed is:

1. A method of manufacturing a semiconductor device, comprising the steps of:
(a) forming a buried oxide film and an SOI layer in the order named on a substrate;
(b) forming an isolation insulation film having a bottom surface positioned inside said SOI layer for partially isolating said SOI layer;
(c) forming a gate electrode on said SOI layer;
(d) forming a first oxide film so as to cover said gate electrode;
(e) forming a nitride film on said first oxide film;
(f) etching said nitride film, with said first oxide film left unremoved, thereby to form a sidewall; and
(g) implanting a first impurity into said SOI layer through said first oxide film to form a first source/drain region.

2. A method of manufacturing a semiconductor device, comprising the steps of:
(a) forming a buried oxide film and an SOI layer in the order named on a substrate;
(b) forming an isolation insulation film having a bottom surface positioned inside said SOI layer for partially isolating said SOI layer;
(c) forming a gate electrode on said SOI layer;
(d) forming a first oxide film so as to cover said gate electrode;
(e) forming a nitride film and a second oxide film in the order named on said first oxide film;
(f) etching said nitride film and said second oxide film, with said first oxide film left unremoved, thereby to form a sidewall; and
(g) implanting a first impurity into said SOI layer through said first oxide film to form a first source/drain region.

3. The method according to claim 1, further comprising the step of
(h) implanting a second impurity having the same conductivity as said first impurity into said SOI layer to form a second source/drain region, said step (h) being performed prior to said step (g).

4. The method according to claim 2, further comprising the step of
(h) implanting a second impurity having the same conductivity as said first impurity into said SOI layer to form a second source/drain region, said step (h) being performed prior to said step (g).

5. The method according to claim 3, wherein
said step (h) is performed subsequently to said step (d).

6. The method according to claim 4, wherein
said step (h) is performed subsequently to said step (d).

7. The method according to claim 1, further comprising the step of
forming an insulation film on a side surface of said gate electrode prior to said step (d),
wherein said insulation film is covered with said first oxide film integrally with said gate electrode in said step (d).

8. The method according to claim 2, further comprising the step of
forming an insulation film on a side surface of said gate electrode prior to said step (d),
wherein said insulation film is covered with said first oxide film integrally with said gate electrode in said step (d).

9. The method according to claim 3, further comprising the step of
forming an insulation film on a side surface of said gate electrode prior to said step (d),
wherein said insulation film is covered with said first oxide film integrally with said gate electrode in said step (d).

10. The method according to claim 4, further comprising the step of
forming an insulation film on a side surface of said gate electrode prior to said step (d),
wherein said insulation film is covered with said first oxide film integrally with said gate electrode in said step (d).

11. The method according to claim 5, further comprising the step of
forming an insulation film on a side surface of said gate electrode prior to said step (d),
wherein said insulation film is covered with said first oxide film integrally with said gate electrode in said step (d).

12. The method according to claim 6, further comprising the step of
forming an insulation film on a side surface of said gate electrode prior to said step (d),
wherein said insulation film is covered with said first oxide film integrally with said gate electrode in said step (d).
